(19) United States
(12) Patent Application Publication
(10) Pub. No.: US 2008/0044739 A1
(43) Pub. Date: Feb. 21, 2008

(54) Correction Of Resist Critical Dimension Variations In Lithography Processes

(75) Inventors: Kenji Konomi, Kanagawa-pref (JP); Seiji Nakagawa, Oita-pref (JP)

Correspondence Address: BANNER & WITCOFF, LTD., 1100 13th STREET, N.W., SUITE 1200, WASHINGTON, DC, 20005-4051, US

(73) Assignee: Toshiba America Electronic Components, Inc., Irvine, CA (US)

(21) Appl. No.: 11/465,185

(22) Filed: Aug. 17, 2006

(51) Int. Cl. G03C 5/00; G06F 17/50; G03F 1/00

(52) U.S. Cl. 430/5; 430/30; 430/394; 716/21

(57) ABSTRACT

According to one aspect, a method is provided for preparing a photoresist mask set adapted to correct for critical dimension variations resulting from topography effects in a semiconductor device. A plurality of rules is established for correcting critical dimension variations resulting from topography effects associated with predetermined structural combinations. A photoresist mask set is then prepared according to rules corresponding to structural combinations present in a semiconductor device to be manufactured.

### FIELD OF THE INVENTION

The present invention is directed to semiconductor manufacturing and, more particularly, to correcting critical dimension variations in lithography processes.

### DESCRIPTION OF RELATED ART

Current demands for high density and performance associated with very large scale integration devices require submicron features, increased transistor and circuit speeds, and improved reliability. These demands require formation of device features with high precision and uniformity, which in turn necessitates careful process monitoring and frequent and detailed inspections of the devices while they are still in the form of semiconductor wafers.

One important process requiring careful inspection is photolithography, wherein masks are used to transfer circuitry patterns to semiconductor wafers. Typically, a series of such masks are employed in a preset sequence. Each photolithographic mask includes an intricate set of geometric patterns corresponding to the circuit components to be integrated onto the wafer. Each mask in the series is used to transfer its corresponding pattern onto a photosensitive layer (i.e., a photoresist layer), which has been previously coated on a layer, such as a polysilicon or metal layer formed on the silicon wafer. The transfer of the mask pattern onto the photoresist layer is conventionally performed by an optical exposure tool such as a scanner or a stepper, which directs light or other radiation through the mask to expose the photoresist. The photoresist is thereafter developed to form a photoresist mask, and the underlying polysilicon or metal layer is selectively etched in accordance with the mask to form features such as lines or gates.

Conventionally, fabrication of the mask follows a set of predetermined design rules set by processing and design limitations. These design rules define the space tolerance between devices and interconnecting lines and the width of the lines themselves, to ensure that the devices or lines do not overlap or interact with one another in undesirable ways. Design rules set limits on critical dimension (“CD”), which may be defined as any linewidth of interest in a device containing a number of different linewidths. The critical dimension for many features in very large scale integration applications typically is on the order of several nanometers.

As the margins for error in semiconductor processing become smaller, inspection and measurement of surface feature's critical dimension, as well as their cross-sectional shape (profile) are becoming increasingly important. Deviations of a feature's critical dimension and profile from design dimensions may adversely affect the performance of the finished semiconductor device. Furthermore, the measurement of a feature's critical dimension and profile may indicate processing problems, such as stepper defocusing or photoresist loss due to overexposure.

One present technique to reduce deviations in post-etch feature critical dimension involves calculating the etch bias of the process. Etch bias is defined as the amount of change in the final dimensions of a feature relative to the “as patterned” dimensions of the photoresist used to form the feature. In effect, etch bias places a value on the accuracy of the pattern transfer from the lithography process to the etch process. For pattern levels where the critical dimension bias is controlled by changes to the etch process for each lot, etch bias prediction is based on the photoresist critical dimension alone. This photoresist critical dimension typically is measured using conventional measurement techniques, such as by using a scanning electron microscope (SEM).

There remains a need for improved techniques for correction of critical dimension variations in lithography processes during semiconductor manufacturing.

### SUMMARY OF THE INVENTION

The present invention, according to one aspect, is directed to a method of preparing a photoresist mask set adapted to correct for critical dimension variations resulting from topography effects in a semiconductor device. A plurality of rules is established for correcting critical dimension variations resulting from topography effects associated with predetermined structural combinations. A photoresist mask set is then prepared according to rules corresponding to structural combinations present in a semiconductor device to be manufactured.

In one aspect, rules for photoresist mask design can be established by sequentially forming layers on a test wafer by a lithography process using test patterns.

Critical dimension variations resulting from topography effects associated with patterns of a layer and one or more previously formed layers are then determined. One or more test patterns used to form the previous layer(s) are then modified to correct for the critical dimension variations.

According to one embodiment of the invention, a method of preparing a photoresist mask includes preparing a first test pattern, coating a first resist on a wafer, and subjecting the first resist to a lithography process according to the first test pattern to form a first layer on the wafer. A second resist is formed on the first layer and is subjected to a lithography process according to a second test pattern to form a second layer on the first layer. Critical dimension variations resulting from topography effects of the first and second layers are determined. The first test pattern is then modified to correct for the critical dimension variations.

By determining critical dimension variations associated with not only a layer formed with a first test pattern, but also previously formed layer(s), it is possible to compensate for topography effects that may result from differences in pattern densities as well as reflective properties associated with different materials, such as silicon and polysilicon, present in a semiconductor device.

### BRIEF DESCRIPTION OF THE DRAWINGS

The objects, features, and advantages of the invention will be apparent from the following more detailed description of certain embodiments of the invention and as illustrated in the accompanying drawings in which:

FIGS. 1A and 1B are scanning electron microscope (SEM) images of wafers with and without topography correction; without topography corrections the wafer has variations in resist width of about 15-20 nm (FIG. 1A); with topography corrections the wafer has variations in resist width of less than 5 nm (FIG. 1B);

FIG. 2 is a top plan view of an exemplary test pattern having a resist portion and gate portions;

FIG. 3 is a schematic illustration of a mask before a topography correction is made; and

FIG. 4 is a schematic illustration of a mask after topography correction is made in accordance with one embodiment of the invention.

### DETAILED DESCRIPTION OF THE INVENTION

It is noted that various connections are set forth between elements in the following description. It is noted that these connections in general and, unless specified otherwise, may be direct or indirect and that this specification is not intended to be limiting in this respect.

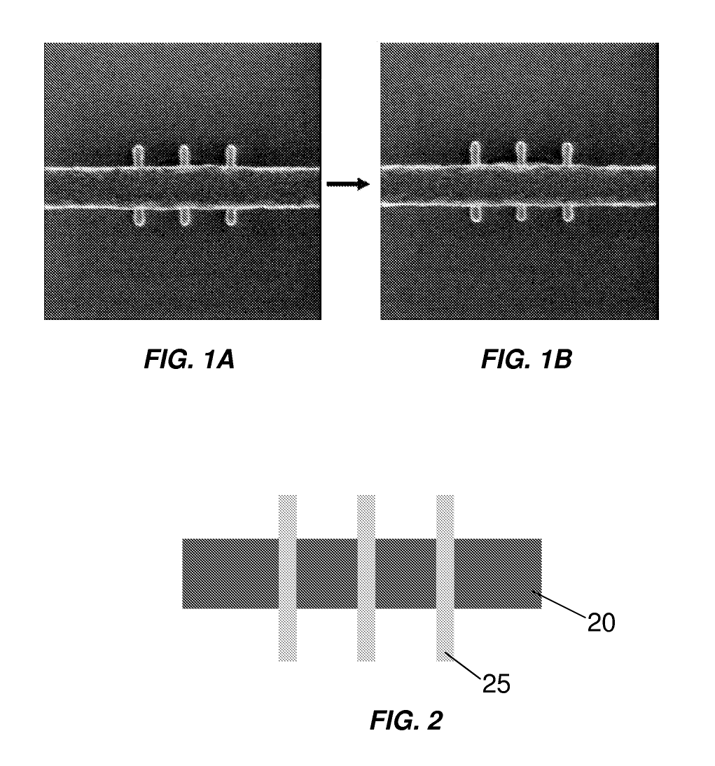

Critical dimension (CD) variations can result from topography effects during lithography processes in semiconductor manufacturing. Topography effects relate not only to pattern distribution and pattern densities, but also the reflective properties of the materials. Different materials commonly used in semiconductor devices, such as silicon and polysilicon, generally have different reflective properties. As a result, different structural combinations present in a semiconductor device can be prone to different (and often unpredictable) CD variations. FIG. 1A shows an example of a silicon wafer prepared without topography correction. The resist width (horizontal band) has a CD variation of about 15-20 nm. As can be seen in FIG. 1A, the CD variation is most pronounced in the areas near the polysilicon gates (vertical “fingers”) due to topography effects. In contrast, when topography corrections are made, the CD variation of the resist width can be significantly reduced, e.g., to less than 5 nm, as seen in FIG. 1B.

In one aspect, a plurality of rules can be established for correcting critical dimension variations resulting from topography effects associated with predetermined structural combinations in a semiconductor device. The rules can be established by forming layers on test wafers using a lithography process with test patterns. FIG. 2 shows an example of a test pattern having a resist portion 20 and several gate (e.g., polysilicon) portions 25.

In an exemplary embodiment, a first test pattern is prepared. A first resist is coated on a wafer, and the first resist is subjected to a lithography process using the first test pattern, thereby forming a first layer on the wafer. A second resist is formed on the first layer and subjected to a lithography process using a second test pattern, thereby forming a second layer on the first layer.

CD variations attributable to topography of a layer and one or more underlying layers can be measured using known techniques, for example with a scanning electron microscope (SEM). The test pattern(s) used to form the previous layer(s) are then modified to correct for the critical dimension variations. For example, if the CD variation in the area of a previously formed polysilicon gate is 13 nm, the corresponding portion of the test pattern used to form the polysilicon gate can be reduced by 13 nm.

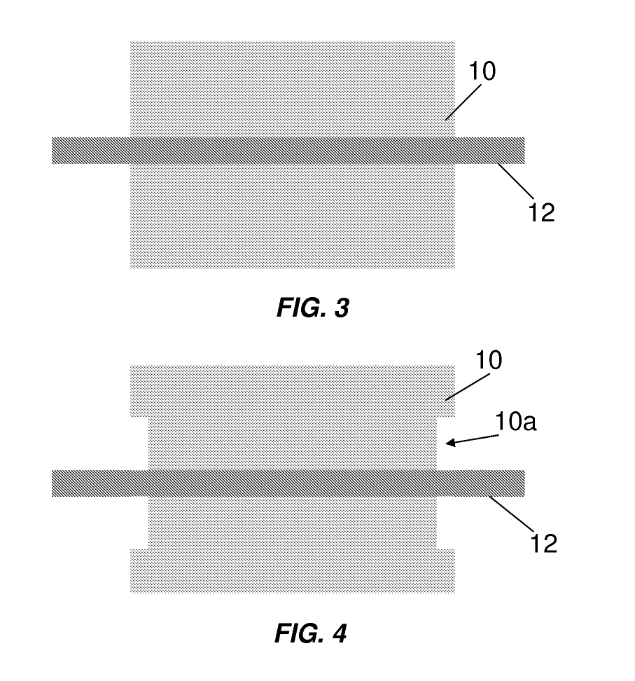

FIGS. 3 and 4 illustrate an exemplary test mask before and after topography correction is made, respectively. The mask has an implant layer 10 and a poly-gate layer 12. As shown in FIG. 4, the implant layer 10 is corrected by forming notches 10a adjacent the poly-gate layer 12 to compensate for topographical effects due to reflective properties of the polysilicon gates.

Once the appropriate modifications are determined for a particular structural configuration, a rule can be established to provide for the necessary CD variation corrections for the configuration. By repeating this technique for different structural combinations, it is possible to create a set of rules to predict (and correct) CD variations for a wide variety of structural combinations that may be present in a semiconductor device. It is contemplated that as many as hundreds of rules, or more, can be created to cover a wide variety of patterns and materials.

The set of rules can be stored in a database and used for automatic CD variation correction during semiconductor manufacturing.

While particular embodiments of the present invention have been described and illustrated, it should be understood that the invention is not limited thereto since modifications may be made by persons skilled in the art. The present application contemplates any and all modifications that fall within the spirit and scope of the underlying invention disclosed and claimed herein.

What is claimed is:

1. A method of preparing a photoresist mask set adapted to correct for critical dimension variations resulting from topography effects in a semiconductor device, the method comprising establishing a plurality of rules for correcting critical dimension variations resulting from topography effects associated with predetermined structural combinations, and preparing a photoresist mask set according to rules corresponding to structural combinations present in a semiconductor device to be manufactured.

2. The method of claim 1 wherein the plurality of rules is established by sequentially forming layers on a test wafer by a lithography process according to a plurality of test patterns; determining critical dimension variations resulting from topography effects associated with a layer so formed and one or more previously formed layers; and modifying one or more test patterns used to form one or more previous layers to correct for the critical dimension variations.

3. A method of preparing a photoresist mask for lithography comprising:
(a) preparing a first test pattern;
(b) coating a first resist on a wafer;
(c) subjecting the first resist to a lithography process according to the first test pattern to form a first layer on the wafer;
(d) coating a second resist on the first layer;
(e) subjecting the second resist to a lithography process according to a second test pattern to form a second layer on the first layer;
(f) determining critical dimension variations resulting from topography effects of the first and second layers;
(g) modifying the first test pattern to correct for the critical dimension variations.

4. The method of claim 3 wherein steps (a)-(g) are repeated for a plurality of test patterns to create a plurality of rules for critical dimension variation corrections.
